(19) United States
(12) Patent Application Publication
(10) Pub. No.: US 2026/0018558 A1
(43) Pub. Date: Jan. 15, 2026

(54) BONDING APPARATUS AND BONDING METHOD

(71) Applicant: WUHAN XINXIN SEMICONDUCTOR MANUFACTURING CO., LTD., WUHAN (CN)

(72) Inventors: Chao TAO, WUHAN (CN); Junzhou LONG, WUHAN (CN); Li WANG, WUHAN (CN)

(73) Assignee: WUHAN XINXIN SEMICONDUCTOR MANUFACTURING CO., LTD., WUHAN (CN)

(21) Appl. No.: 19/332,997

(22) Filed: Sep. 18, 2025

Related U.S. Application Data
(63) Continuation of application No. PCT/CN2023/140750, filed on Dec. 21, 2023.

(30) Foreign Application Priority Data
Jul. 7, 2023 (CN) 202310837683.5

(51) Int. Cl. H01L 23/00

(52) U.S. Cl. CPC H01L 24/80; H01L 24/74; H01L 2224/74; H01L 2224/8013; H01L 2224/8017; H01L 2224/80895; H01L 2224/80896

(57) ABSTRACT

A bonding apparatus and a bonding method are provided. The bonding apparatus includes: a machine base, including a movable pick-up platform; and a laser interferometer assembly. The laser interferometer assembly includes: a first laser interferometer unit, configured to determine displacement information of the movable pick-up platform along a first direction; and a second laser interferometer unit, configured to determine displacement information of the movable pick-up platform along a second direction. Based on the displacement information along the first direction and the displacement information along the second direction, the laser interferometer assembly is further configured to determine coordinate information of the movable pick-up platform.

### CROSS REFERENCE TO RELATED APPLICATIONS

The present application is a continuation-application of International (PCT) Patent Application No. PCT/CN2023/140750, filed Dec. 21, 2023, which claims foreign priority to Chinese Patent Application No. 202310837683.5, filed Jul. 7, 2023, both of which is incorporated herein in their entireties.

### TECHNICAL FIELD

The present disclosure relates to the field of semiconductor manufacturing technologies, and in particular to a bonding apparatus and a bonding method.

### BACKGROUND

As a semiconductor technology enters a post-Moore era, a structure of a chip is developing in a three-dimensional integration direction, so as to meet the requirement of high integration and high performance. A bonding technology is one of the important “More than Moore” technologies. A semiconductor bonding technology refers to a technology of directly combining two pieces of homogeneous or heterogeneous semiconductor materials after surface cleaning and activation treatment. Under a certain condition, wafers are bonded into one through van der Waals forces, molecular forces, or even atomic forces. Bonding accuracy is an important parameter of the bonding process and has a significant impact on the application of the bonding process.

### SUMMARY OF THE DISCLOSURE

According to a first aspect, some embodiments of the present disclosure provide a bonding apparatus. The bonding apparatus may include: a machine base, including a movable pick-up platform; and a laser interferometer assembly including: a first laser interferometer unit, configured to determine displacement information of the movable pick-up platform along a first direction; and a second laser interferometer unit, configured to determine displacement information of the movable pick-up platform along a second direction; where based on the displacement information along the first direction and the displacement information along the second direction, the laser interferometer assembly is further configured to determine coordinate information of the movable pick-up platform.

According to a second aspect, some embodiments of the present disclosure provide a bonding method. The bonding method may include: reading a first alignment mark and a second alignment mark on a to-be-bonded first component; reading a third alignment mark and a fourth alignment mark on a to-be-bonded second component; determining a calibrated coordinate system based on the first alignment mark and the second alignment mark or based on the third alignment mark and the fourth alignment mark; determining a fixed coordinate in the calibrated coordinate system; determining first-direction coordinate information and second-direction coordinate information based on the first alignment mark, the second alignment mark, the third alignment mark, the fourth alignment mark, and the fixed coordinate; determining a bonding alignment position of the to-be-bonded first component and the to-be-bonded second component based on the first-direction coordinate information and the second-direction coordinate information; and bonding the to-be-bonded second component to a predetermined surface position of the to-be-bonded first component.

Specific embodiments and technical details are further described below with reference to the accompanying drawings. Other features, objectives, and advantages of the present disclosure will become apparent from the description, drawings, and claims.

### BRIEF DESCRIPTION OF THE DRAWINGS

In order to more clearly illustrate the technical solutions in the embodiments of the present disclosure, the following is a brief description of the drawings required for the description of the embodiments, and it will be obvious that the drawings in the following description are only some embodiments of the present disclosure, and that other drawings may be obtained from these drawings without creative work for those skilled in the art.

FIG. 1 is a schematic structural diagram of a bonding apparatus according to some embodiments of the present disclosure from a first view angle.

FIG. 2 is a schematic structural diagram of a partial structure of the bonding apparatus shown in FIG. 1 from a second view angle.

FIG. 3 is a schematic diagram of a process in which the bonding apparatus determines a first alignment mark and a second alignment mark on a first component according to some embodiments of the present disclosure.

FIG. 4 is a schematic diagram of a process in which the bonding apparatus identifies a correction mark according to some embodiments of the present disclosure.

FIG. 5 is a schematic diagram of a calibrated coordinate system defined by the bonding apparatus according to some embodiments the present disclosure.

FIG. 6 is a schematic diagram of a process in which the bonding apparatus determines a third alignment mark and a fourth alignment mark on a second component according to some embodiments of the present disclosure.

FIG. 7 is a schematic diagram of a process in which the bonding apparatus determines coordinate information along a first direction and coordinate information along a second direction according to some embodiments of the present disclosure.

FIG. 8 is a schematic diagram of a process in which the bonding apparatus corrects coordinate information of a relative position between the second component and the first component in the calibrated coordinate system according to some embodiments of the present disclosure.

FIG. 9 is a schematic diagram of a process in which the bonding apparatus bonds the second component to a predetermined surface position of the first component according to some embodiments of the present disclosure.

FIG. 10 is a schematic diagram of the coordinate information in the calibrated coordinate system when the second component is bonded to the predetermined surface position of the first component as shown in FIG. 9.

FIG. 11 is a schematic flowchart of a bonding method according to some embodiments of the present disclosure.

FIG. 12 is a schematic structural diagram of a laser interferometer assembly according to some embodiments of the present disclosure.

### DETAILED DESCRIPTION

The technical solutions in embodiments of the present disclosure will be clearly and completely described below in conjunction with the accompanying drawings in the embodiments of the present disclosure, and it is obvious that the described embodiments are only a part of the embodiments of the present disclosure, but not all of them. Based on the embodiments in the present disclosure, all other embodiments obtained by those skilled in the art without creative labor fall within the scope of the present disclosure.

The terms “first”, “second”, and “third” in the present disclosure are intended for descriptive purposes only and are not to be construed as indicating or implying relative importance or implicitly indicating the number of indicated technical features. Therefore, a feature defined with “first”, “second”, or “third” may explicitly or implicitly include at least one such feature. In the description of the present disclosure, “a plurality of” or “multiple” means at least two, e.g., two, three, etc., unless otherwise expressly and specifically limited. All directional indications (e.g., up, down, left, right, forward, backward . . . ) in the present disclosure are intended only to explain the relative position relationship, movement, etc., between components in a particular posture (as shown in the accompanying drawings), and if that particular posture is changed, the directional indications are changed accordingly. In addition, the terms “include” and “have”, and any variations thereof are intended to cover non-exclusive inclusion. For example, a process, method, system, product, or apparatus including a series of steps or units is not limited to the listed steps or units, but In some embodiments further may include steps or units not listed, or In some embodiments further may include other steps or units inherent to the process, method, product, or apparatus.

References herein to “embodiment” mean that particular features, structures, or characteristics described in connection with an embodiment can be included in at least one embodiment of the present disclosure. The presence of the phrase at various positions in the specification does not necessarily mean the same embodiment, nor is it a separate or alternative embodiment that is mutually exclusive with other embodiments. It is understood, both explicitly and implicitly, by those skilled in the art that the embodiments described herein can be combined with other embodiments.

The present disclosure may be described in detail below in conjunction with the accompanying drawings and embodiments.

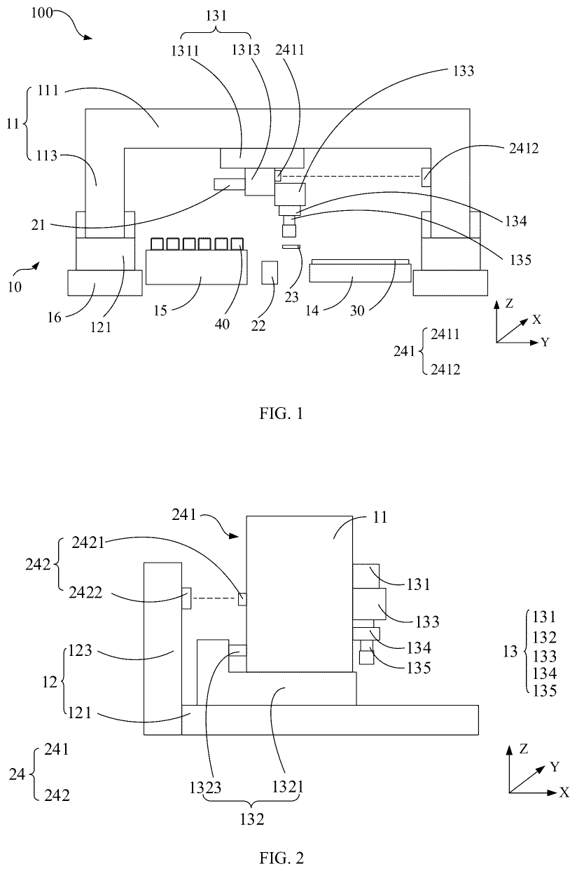

As shown in FIGS. 1-2, FIG. 1 is a schematic structural diagram of a bonding apparatus according to some embodiments of the present disclosure from a first view angle. FIG. 2 is a schematic structural diagram of a partial structure of the bonding apparatus shown in FIG. 1 from a second view angle. In some embodiments, as shown in FIGS. 1-2, a bonding apparatus 100 may include a machine base 10 and a laser interferometer assembly 24 arranged on the machine base 10. The machine base 10 may include a gantry 11, a base frame 12, a movable pick-up platform 13, and a first chuck 14. In some embodiments, the first chuck 14 is arranged on the machine base 10. The first chuck 14 is configured to carry a to-be-bonded first component 30. It should be noted that the first component 30 described as below may be referred to the to-be-bonded first component 30 before bonding, and for the sake of brevity, the to-be-bonded first component 30 may be described as the first component 30. The gantry 11 is arranged on the base frame 12. A position of the movable pick-up platform 13 is controlled by the gantry 11 and the base frame 12, such that it may be possible to enable the movable pick-up platform 13 to be configured to pick up a to-be-bonded second component 40, and move the picked-up second component 40 to a predetermined surface position of the first component 30. It should be noted that the second component 40 described as below may be referred to the to-be-bonded second component 40 before bonding, and for the sake of brevity, the to-be-bonded second component 40 may be described as the second component 40. In some embodiments, the laser interferometer assembly 24 may include a first laser interferometer unit 241 and a second laser interferometer unit 242. The first laser interferometer unit 241 is arranged on the gantry 11, and configured to determine displacement information of the movable pick-up platform 13 along a first direction Y. A position of the second laser interferometer unit 242 is controlled by the gantry 11 and the base frame 12. The second laser interferometer unit 242 may be capable of determining displacement information of the movable pick-up platform 13 along a second direction X. Based on the displacement information along the first direction Y and the displacement information along the second direction X, the laser interferometer assembly 24 may be further capable of determining coordinate information of the second component 40 along the first direction Y and coordinate information of the second component 40 along the second direction X.

In some embodiments, the bonding apparatus 100 may further include a reference assembly arranged on the machine base 10. The reference assembly may be configured to correct/adjust a relative position between the first component 30 and the second component 40 according to correction information. In some embodiments, the reference assembly may also be referred to as a correction assembly.

It may be understood that in some embodiments, the first component 30 may be a wafer or a chip. Correspondingly, the second component 40 may be the wafer or the chip.

In some embodiments, the gantry 11 may be approximately in a shape of a door frame. The gantry 11 may include a top plate 111 and two first side plates 113. The two first side plates 113 may be connected to the top plate 111, respectively. The two first side plates 113 are opposite to each other. A door-frame structure of the gantry 11 may be formed by the top plate 111 and the first two side plates 113. The base frame 12 may include a bottom plate 121 and a second side plate 123 connected to the bottom plate 121. The bottom plate 121 of the base frame 12 is opposite to the top plate 111 of the gantry 11. The second side plate 123 of the base frame 12 is opposite to the first side plate 113 of the gantry 11. In some embodiments, the bottom plate 121 may be approximately perpendicular to the second side plate 123.

In some embodiments, the machine base 10 may further include a second chuck 15. The second chuck 15 is arranged on the machine base 10. The second chuck 15 and the first chuck 14 may be disposed side by side. The second chuck 15 may be configured to carry the second component 40. In some embodiments, the first chuck 14 and/or the second chuck 15 may further be arranged on the bottom plate 121 of the base frame 12.

In some embodiments, the machine base 10 may further include a base 16 arranged on a side of the bottom plate 121 away from the first side plate 113. The movable pick-up platform 13, the gantry 11, and the bottom plate 121 of the base frame 12 may be installed on the base 16. In some embodiments, the base 16 may be made of marble. A vibration isolation and damping device may also be arranged at a bottom of the base 16, and may be configured to reduce the vibration caused by the movable pick-up platform 13 during a process of moving and bonding the second component 40 to the predetermined surface position of the first component 30, thereby improving the stability of the bonding apparatus 100.

Further as shown in FIGS. 1-2, in some embodiments, the movable pick-up platform 13 may be a macro-micro dual-stage motion mechanism. In some embodiments, the movable pick-up platform 13 may include a first driving member 131 and a second driving member 132. The first driving member 131 may be disposed at a side of the top plate 111 of the gantry 11 facing the first chuck 14. The second driving member 132 may be disposed at a side of the bottom plate 121 of the base frame 12 facing the gantry 11. The gantry 11 may be disposed on the bottom plate 121 of the base frame 12 through the second driving member 132. In some embodiments, the movable pick-up platform 13 may further include a third driving member 133, and the third driving member 133 is disposed at a side of the first driving member 131. In some embodiments, the movable pick-up platform 13 may further include a rotation driving member 134 and a bonding head 135. The rotation driving member 134 is disposed at a bottom of the third driving member 133. The bonding head 135 is connected to the rotation driving member 134. The first driving member 131 may be configured to move the third driving member 133 and the rotation driving member 134 along the first direction Y in a horizontal plane, such that the bonding head 135 may be moved along the first direction Y in the horizontal plane. The second driving member 132 may be configured to move the gantry 11 along the second direction X in the horizontal plane, such that the bonding head 135 may be moved along the second direction X. In some embodiments, the third driving member 133 may be configured to move the rotation driving member 134 along a third direction Z in a plane approximately perpendicular to the horizontal plane, such that the bonding head 135 may be moved along the third direction Z. The rotation driving member 134 may be configured to rotate the bonding head 135, so as to enable the bonding head 135 to pick up the second component 40, and thus the second component 40 may be bonded to the predetermined surface position of the first component 30.

In some embodiments, the first driving member 131 may include a first macro-driving member 1311 and a first micro-driving member 1313. The first macro-driving member 1311 may be disposed at the side of the top plate 111 of the gantry 11 facing the first chuck 14. The first macro-driving member 1311 may be configured to coarsely move/coarsely adjust the third driving member 133 and the rotation driving member 134 along the first direction Y in the horizontal plane, such that the bonding head 135 may be moved along the first direction Y in the horizontal plane. The first micro-driving member 1313 may be disposed at a side of the first macro-driving member 1311 away from the top plate 111. The first micro-driving member 1313 may be configured to finely move/finely adjust the third driving member 133 and the rotation driving member 134 along the first direction Y in the horizontal plane, such that the bonding head 135 may be finely moved along the first direction Y in the horizontal plane. The first macro-driving member 1311 may be configured to coarsely move the bonding head 135 along the first direction Y and perform coarse positioning with sub-micron accuracy. The first micro-driving member 1313 may finely move the bonding head 135 along the first direction Y and perform positioning with sub-micron accuracy through error compensation mechanisms. In this way, the first driving member 131 may implement the positioning with sub-micron accuracy of the bonding head 135 along the first direction Y through the coordinated actuation of the first macro-driving member 1311 and the first micro-driving member 1313 along the first direction Y.

In some embodiments, the second driving member 132 may include a second macro-driving member 1321 and a second micro-driving member 1323. The second macro-driving member 1321 may be disposed at the side of the bottom plate 121 of the base frame 12 facing the gantry 11. The second macro-driving member 1321 may be configured to coarsely move the gantry 11 along the second direction X in the horizontal plane, such that the bonding head 135 may be moved along the second direction X in the horizontal plane. The second micro-driving member 1323 may be connected to the second macro-driving member 1321 and the first side plate 111 of the gantry 11. The second micro-driving member 1323 may be configured to finely move the gantry 11 along the second direction X in the horizontal plane, such that the bonding head 135 may be finely moved along the second direction X in the horizontal plane. The second macro-driving member may coarsely move the bonding head 135 along the second direction X and perform coarse positioning with the sub-micron accuracy. The second micro-driving member 1323 may finely move the bonding head 135 along the second direction X and perform positioning with sub-micron accuracy through the error compensation mechanisms. In this way, the second driving member 132 may implement the positioning with sub-micron accuracy of the bonding head 135 along the second direction X through the coordinated actuation of the second macro-driving member 1321 and the second micro-driving member 1323 along the second direction X.

Accordingly, the third driving member 133 may move the rotation driving member 134 along the third direction Z, such that the third driving member 133 may implement accurate positioning of the bonding head 135 along the third direction Z. The rotation driving member 134 may implement positioning with micro-radian-level accuracy.

It should be noted that, each of the first driving member 131, the second driving member 132, the third driving member 133, and the rotation driving member 134 may further include a motor, such as a linear motor or a rotary motor. The motor may be configured to provide power to a corresponding driving member as described above. It may be understood that a structural design of the first macro-driving member or the first micro-driving member provided in the embodiments of the present disclosure may also be referred to a specific structure in the related art, as long as the structural design thereof may realize a function of moving the bonding head 135 along the first direction Y in the horizontal plane and implementing the positioning with sub-micron accuracy, which are not limited herein. Accordingly, a structural design of each of the third driving member 133, the second macro-driving member, the second micro-driving member, and the rotation driving member 134 may also be referred to a specific structure in the related art, as long as the structural design thereof may realize a corresponding function thereof.

In some embodiments, the first direction Y, the second direction X, and the third direction Z may be mutually perpendicular to each other. In some embodiments, the first direction Y may be approximately parallel to a Y-axis direction, the second direction X may be approximately parallel to an X-axis direction, and the third direction Z may be approximately parallel to a Z-axis direction. Correspondingly, the first macro-driving member 1311 and the first micro-driving member 1313 may also be referred to as a Y-axis macro-driving member and a Y-axis micro-driving member, respectively. The second macro-driving member 1321 and the second micro-driving member 1323 may also be referred to as an X-axis macro-driving member and an X-axis micro-driving member, respectively. The third driving member 133 may also be referred to as a Z-axis driving member.

In some embodiments, the movable pick-up platform 13 may also be a single-stage motion mechanism or other types of motion mechanisms, as long as the motion mechanism may be capable of moving the second component 40 to the predetermined surface position of the first component 30 and bonding the second component 40 to the predetermined surface position of the first component 30 in a case where the specific accuracy requirement may be met.

Further as shown in FIGS. 1-2 and in combination with FIGS. 3-10, FIGS. 3-10 illustrate schematic diagrams of a working process of the bonding apparatus 100 according to some embodiments of the present disclosure. As shown in FIGS. 1-2, the bonding apparatus 100 may further include a first image acquisition member 21 and a second image acquisition member 22.

In some embodiments, the first image acquisition member 21 may have a first viewing angle. The first image acquisition member 21 may be configured to read a first alignment mark B1 and a second alignment mark B2 on the first component 30. The first image acquisition member 21 may be disposed at a side of the first micro-driving member 1313 away from the third driving member 133, such that the first image acquisition member 21 may be capable of precisely moving with the first driving member 131. The first viewing angle may also be referred to as a downward viewing angle. It may be understood that a position at which the first image acquisition member 21 is disposed may not be limited to the side of the first micro-driving member 1313 away from the third driving member 133. In some embodiments, the first image acquisition member 21 may be disposed at any position of the first micro-driving member 1313 according to specific design requirements, as long as the first image acquisition member 21 may be capable of precisely moving with the first driving member 131 and may be capable of reading the first alignment mark B1 and the second alignment mark B2 on the first component 30.

As shown in FIG. 3, FIG. 3 is a schematic diagram of a process in which the bonding apparatus determines a first alignment mark and a second alignment mark on a first component according to some embodiments of the present disclosure. As shown in FIG. 3, during a process in which the movable pick-up platform 13 moves the second component 40 and bonds the second component 40 to the predetermined surface position of the first component 30, the first image acquisition member 21 may be capable of moving with the first driving member 131. In some embodiments, the first image acquisition member 21 may be capable of moving with the first driving member 131 to a position above the first chuck 14 carrying the first component 30, i.e., the position may correspond to a direction of the first chuck 14 facing the top plate 111 of the gantry 11. At this time, a field-of-view of the first image acquisition member 21 may be positioned above the first alignment mark B1 on the first component 30, such that the first image acquisition member 21 may read the first alignment mark B1 on the first component 30. The first image acquisition member 21 may be driven to continue to move until the field-of-view of the first image acquisition member 21 may be positioned above the second alignment mark B2 on the first component 30, such that the first image acquisition member 21 may read the second alignment mark B2 on the first component 30. That is, when the field-of-view of the first image acquisition member 21 is positioned within an area where the first component 30 is located, the first image acquisition member 21 may be capable of reading the first alignment mark B1 and the second alignment mark B2 on the first component 30.

The second image acquisition member 22 may be disposed on the machine base 10. The second image acquisition member 22 may have a second viewing angle, and may be capable of reading a third alignment mark T1 and a fourth alignment mark T2 on the second component 40. The second viewing angle may also be referred to as an upward viewing angle. In some embodiments, the movable pick-up platform 13 may be controlled to move the bonding head 135, such that the picked-up second component 40 may be moved to a position above the second image acquisition member 22 until the second image acquisition member 22 may be capable of reading the third alignment mark T1 and the fourth alignment mark T2 on the second component 40.

In some embodiments, each of the first image acquisition member 21 and the second image acquisition member 22 may be a camera. In some embodiments, the first image acquisition member 21 may also be referred to as a downward-looking camera. The second image acquisition member 22 may also be referred to as an upward-looking camera.

In some embodiments, the reference assembly may include a reference member 23. The reference member 23 may be disposed on the machine base 10. The reference member 23 may be driven to move freely between the top plate 111 of the gantry 11 and the second image acquisition member 22. For example, the reference member 23 may be driven to move freely between the bonding head 135 and the second image acquisition member 22. Alternatively, the reference member 23 may be driven to move freely between the first image acquisition member 21 and the second image acquisition member 22. A free movement range of the reference member 23 is not less than an intersection of a maximum field-of-view of the first image acquisition member 21 and a maximum field-of-view of the second image acquisition member 22. In some embodiments, the reference member 23 may be driven to move freely between the top plate 111 of the gantry 11 and the second image acquisition member 22 by means of a cylinder or a motor. In some embodiments, the reference member 23 may include a transparent component, a translucent component, or a structural component with a through-hole. A reference mark 231 may be arranged on the reference member 23. Of course, the reference member 23 may also be other structural designs, as long as the structural design may enable the first image acquisition member 21 to recognize the reference mark on the second image acquisition member 22 through the reference member 23, or may enable the second image acquisition member 22 to recognize the reference mark on the first image acquisition member 21 through the reference member 23. It may be understood that the reference member 23 may be a calibration piece. Accordingly, the reference mark 231 may also be a calibration mark disposed on the calibration piece.

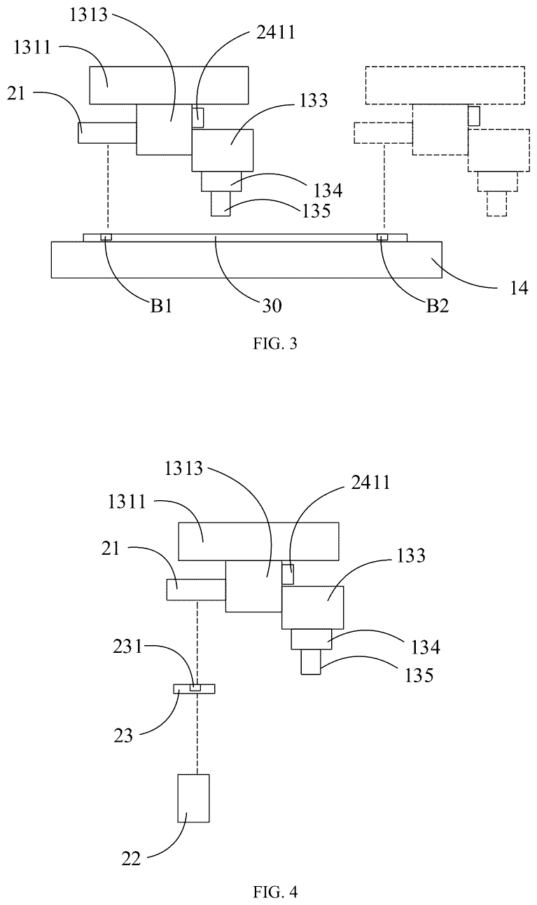

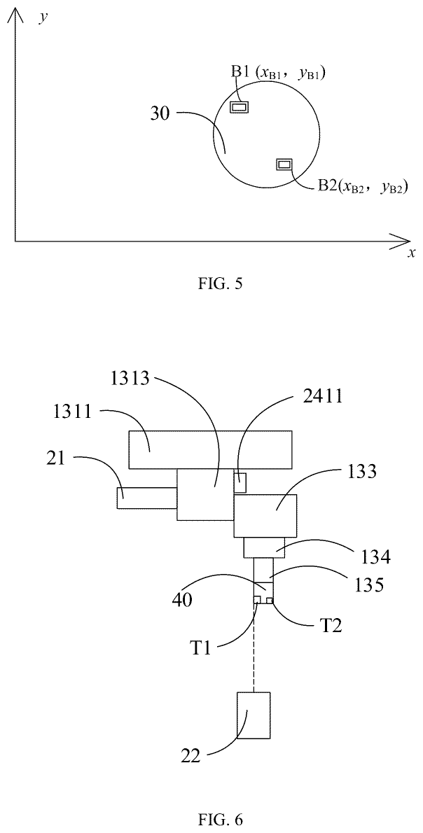

As shown in FIGS. 4-6, FIG. 4 is a schematic diagram of a process in which the bonding apparatus identifies a correction mark according to some embodiments of the present disclosure. FIG. 5 is a schematic diagram of a calibrated coordinate system defined by the bonding apparatus according to some embodiments the present disclosure. FIG. 6 is a schematic diagram of a process in which the bonding apparatus determines a third alignment mark and a fourth alignment mark on a second component according to some embodiments of the present disclosure.

In some embodiments, based on the read first alignment mark B1 and the read second alignment mark B2, the second image acquisition member 22 may cooperate with the reference member 23 and the first image acquisition member 21 to define a calibrated coordinate system/correction coordinate system. In some embodiments, the first image acquisition member 21 may be driven to move with the first driving member 131. For example, the first image acquisition member 21 may be driven to move to the position above the second image acquisition member 22 until a connecting line between a center point of the first image acquisition member 21 and a center point of the second image acquisition member 22 is approximately perpendicular to a plane at which the first chuck 14 is located, i.e., the center point of the first image acquisition member 21 and the center point of the second image acquisition member 22 may be aligned with each other in a direction approximately parallel to the third direction Z. In some embodiments, the reference member 23 is moved to the position above the second image acquisition member 22, and is moved to be located between the first image acquisition member 21 and the second image acquisition member 22. At this time, a connecting line between the center point of the first image acquisition member 21, a center point of the reference member 23, and the center point of the second image acquisition member 22 may be approximately perpendicular to the plane at which the first chuck 14 is located. In this way, the reference mark 231 may be simultaneously recognized by the first image acquisition member 21 and the second image acquisition member 22, such that it may be possible to determine the fixed coordinate in the calibrated coordinate system. That is, the first image acquisition member 21 and the reference member 23 may be moved to the position above the second image acquisition member 22, and the center point of the first image acquisition member 21, the center point of the reference member 23, and the center point of the second image acquisition member 22 may be aligned with each other in the direction approximately parallel to the third direction Z at the same time. The first image acquisition member 21 and the second image acquisition member 22 may be configured to simultaneously recognize the reference mark 231, such that it may be possible to determine the fixed coordinate in the calibrated coordinate system. In some embodiments, the fixed coordinate may be an origin coordinate in the calibrated coordinate system.

It may be understood that, the center point of the first image acquisition member 21 may be a center of the field-of-view of the first image acquisition member 21. Accordingly, the center point of the second image acquisition member 22 may be a center of the field-of-view of the second image acquisition member 22.

In some embodiments, since position information corresponding to the first alignment mark B1 and the second alignment mark B2 on the first component 30 read by the first image acquisition member 21 and position information corresponding to the third alignment mark T1 and the fourth alignment mark T2 on the second component 40 read by the second image acquisition member 22 respectively correspond to different coordinate systems, in a structural design of the bonding apparatus provided in the embodiments of the present disclosure, by arranging the reference member 23 and enabling the first image acquisition member 21 and the second image acquisition member 22 to simultaneously recognize the reference mark 231, the field-of-view of the first image acquisition member 21 and the field-of-view of the second image acquisition member 22 may be aligned with a same object, i.e., the reference mark 231 on the reference member 23. At this time, it should be considered that the first image acquisition member 21 and the second image acquisition member 22 may be aligned with each other. Therefore, the position information of the second image acquisition member 22 may be first determined by the first image acquisition member 21, the first image acquisition member 21 and the second image acquisition member 22 may simultaneously recognize the reference mark 231, and the position information corresponding to the reference mark 231 read by the first image acquisition member 21 and the second image acquisition member 22 may be converted into a same coordinate system, i.e., the calibrated coordinate system, such that it may be possible to determine the fixed coordinate in the calibrated coordinate system.

In other embodiments, the reference member 23 may not be provided, and the reference mark 231 may be disposed on a certain member of the bonding apparatus. That is, the reference mark 231 may also be disposed on the certain member of the bonding apparatus. For example, the reference mark 231 may be disposed on the second image acquisition member 22, and the reference mark 231 may be read by the first image acquisition member 21, such that it may also be possible to determine the fixed coordinate in the calibrated coordinate system.

In some embodiments, the second image acquisition member 22 may be further configured to read the third alignment mark T1 and the fourth alignment mark T2 on the second component 40 picked up by the bonding head 135 according to the calibrated coordinate system. In some embodiments, as shown in FIG. 6, after the fixed coordinate in the calibrated coordinate system is determined, the reference member 23 may be moved away, for example, the reference member 23 may be moved out of the maximum field-of-view of the first image acquisition member 21 or the maximum field-of-view of the second image acquisition member 22. The movable pick-up platform 13 may be controlled to pick up the second component 40 through the bonding head 135, and the picked-up second component 40 may be moved to the position above the second image acquisition member 22 until the field-of-view of the second image acquisition member 22 is positioned below the third alignment mark T1 and the fourth alignment mark T2 on the second component 40, i.e., a position may correspond to a direction of an end of the bonding head 135 facing the second image acquisition member 22. Therefore, the second image acquisition member 22 may read the third alignment mark T1 and the fourth alignment mark T2 on the second component 40. In this way, the third alignment mark T1 and the fourth alignment mark T2 on the second component 40 picked up by the bonding head 135 may be read by the second image acquisition member 22.

It may be understood that the reference member 23 may also be disposed at other positions in the bonding apparatus 100, as long as the following condition may be met. That is, when it is necessary to determine the fixed coordinate in the calibrated coordinate system, the reference member 23 may be moved between the first image acquisition member 21, and the center point of the first image acquisition member 21, the center point of the reference member 23, and the center point of the second image acquisition member 22 may be aligned with each other in the direction approximately parallel to the third direction Z at the same time. After the fixed coordinate is determined, the reference member 23 may be moved away, for example, the reference member 23 may be moved out of the maximum field-of-view of the first image acquisition member 21 or the maximum field-of-view of the second image acquisition member 22.

In some embodiments, the reference member 23 may have an appropriate thickness and a thermal expansion coefficient, such that it may be possible to reduce a difference between an optical path of the first image acquisition member 21 reaching the reference member 23 and an optical path of the second image acquisition member 22 reaching the reference member 23.

In some embodiments, the calibrated coordinate system may also be referred to as a bonding coordinate system, and may include an X-axis and a Y-axis.

In other embodiments, the fixed coordinate in the calibrated coordinate system may also be determined by the first image acquisition member 21 and the second image acquisition member 22. In some embodiments, the second image acquisition member 22 may be fixedly disposed on the machine base 10, and thus a position at which the second image acquisition member 22 is disposed is fixed. Based on the read first alignment mark B1 and the read second alignment mark B2, the calibrated coordinate system may be defined. In some embodiments, the first image acquisition member 21 may be driven to move with the first driving member 131. For example, the first image acquisition member 21 may be driven to move to the position above the second image acquisition member 22 until a connecting line between a center point of the first image acquisition member 21 and a center point of the second image acquisition member 22 is approximately perpendicular to a plane at which the first chuck 14 is located, i.e., the center point of the first image acquisition member 21 and the center point of the second image acquisition member 22 may be aligned with each other in a direction approximately parallel to the third direction Z, such that it may be possible to determine the fixed coordinate in the calibrated coordinate system.

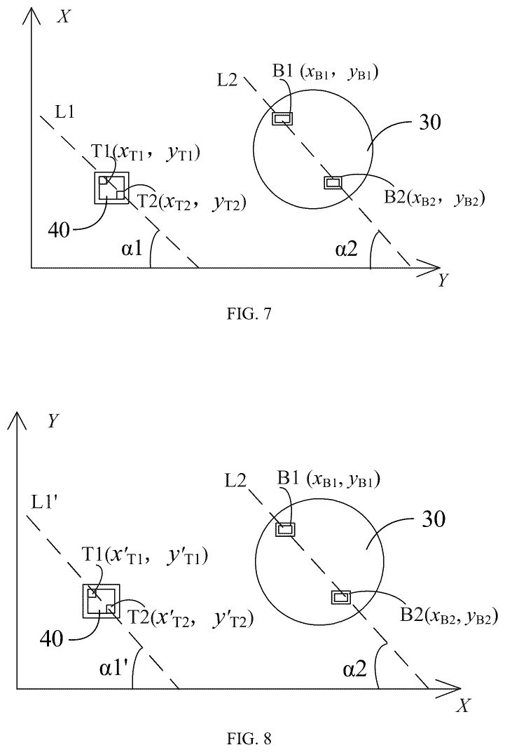

Further as shown in FIGS. 1-2 and in combination with FIGS. 7 to 11, in some embodiments, based on a coordinate relationship/positional relationship of the first alignment mark B1, the second alignment mark B2, the third alignment mark T1, and the fourth alignment mark T2 in the calibrated coordinate system, the laser interferometer assembly 24 may be configured to determine an angular deviation between the first component 30 and the second component 40 in the calibrated coordinate system. In some embodiments, the laser interferometer assembly 24 may further cooperate with the first driving member 131, the second driving member 132, the third driving member 133, and the rotation driving member 134 to adjust a position of the second component 40 through the bonding head 135.

In some embodiments, as shown in FIG. 7, FIG. 7 is a schematic diagram of a process in which the bonding apparatus determines coordinate information along a first direction and coordinate information along a second direction according to some embodiments of the present disclosure. In the calibrated coordinate system, a first connecting line between the third alignment mark T1 and the fourth alignment mark T2 on the second component 40 may be assumed to be L1. A first angle between the L1 and the X-axis direction in the calibrated coordinate system may be assumed to be α1. A second connecting line between the first alignment mark B1 and the second alignment mark B2 on the first component 30 may be assumed to be L2. A second angle between the L2 and the X-axis direction in the calibrated coordinate system may be assumed to be α2. An angular deviation Δα between the first component 30 and the second component 40 in the calibrated coordinate system is an absolute value of a difference between the first angle α1 and the second angle α2, i.e., Δα=|α2−α1|.

In some embodiments, as shown in FIGS. 1-2, in the structural design of the laser interferometer assembly 24, the number of first laser interferometer units 241 is at least one group. The number of second laser interferometer units 242 is at least one group. The first laser interferometer unit 241 may include a first reflective mirror 2411 and a first laser interferometer 2412. The first reflective mirror 2411 and the first laser interferometer 2412 may be configured to synchronously move with the movable pick-up platform 13 along the second direction X. The second laser interferometer unit 242 may include a second reflective mirror 2421 and a second laser interferometer 2422. The second reflective mirror 2421 and the second laser interferometer 2422 may be configured to synchronously move with the movable pick-up platform 13 along the first direction Y.

In some embodiments, in a structural design of the first laser interferometer unit 241, the first reflective mirror 2411 may be disposed on the movable pick-up platform 13. For example, the first reflective mirror 2411 and the rotation driving member 134 may be disposed at a same side of the first micro-driving member 1313. The first laser interferometer 2412 may be disposed at a side plate of the gantry 11. Alternatively, the positions of the first reflective mirror 2411 and the first laser interferometer 2412 may be interchanged. That is, the first reflective mirror 2411 may be disposed at the side plate of the gantry 11. The first laser interferometer 2412 may be disposed on the movable pick-up platform 13. For example, the first laser interferometer 2412 and the rotation driving member 134 may be disposed at a same side of the first micro-driving member 1313. In other words, the first reflective mirror 2411 may be disposed on one of the movable pick-up platform 13 and a side plate of the gantry 11, and the first laser interferometer 2412 may be disposed on the other one of the movable pick-up platform 13 and the side plate of the gantry 11. In some embodiments, in a plane approximately parallel to the side plate of the gantry 11, a projection of the first reflective mirror 2411 may be at least partially overlapped with that of the first laser interferometer 2412. It may be understood that the plane approximately parallel to the side plate of the gantry 11 may be referred to a plane approximately parallel to the third direction Z shown in FIG. 1 and approximately perpendicular to the first direction Y shown in FIG. 1, i.e., a plane approximately parallel to the third direction Z shown in FIG. 1 and approximately parallel to the second direction X shown in FIG. 1. In some embodiments, the first laser interferometer 2412 may be configured to emit a first correction laser beam along the first direction Y. The first reflective mirror 2411 may be configured to receive the first correction laser beam. The first reflective mirror 2411 may be configured to receive the first correction laser beam along the first direction Y and generate a first reflected laser beam along the first direction Y. The first laser interferometer 2412 may be configured to receive the first reflected laser beam. In this way, it may be possible to enable the first laser interferometer 2412 and the first reflective mirror 2411 to cooperate to determine a coordinate relationship of the first alignment mark B1, the second alignment mark B2, the third alignment mark T1, and the fourth alignment mark T2 along the first direction Y. The first correction laser beam and the first reflected laser beam have a same fixed wavelength. In some embodiments, the first correction laser beam may be referred to as a first laser beam. The first reflected laser beam may also be referred to as a reflected first laser beam.

In some embodiments, the first laser interferometer 2412 may include a first system connection line. The first system connection line may be configured to be connected to a computer system 243. Based on the determined coordinate relationship along the first direction Y, the computer system 243 may be configured to generate first-direction coordinate information (i.e., the coordinate information along the first direction Y) related to the coordinate relationship of the first alignment mark B1, the second alignment mark B2, the third alignment mark T1, and the fourth alignment mark T2 along the first direction Y.

In some embodiments, when the first micro-driving member 1313 finely moves the third driving member 133 and the rotation driving member 134 in the horizontal plane along the first direction Y, resulting in a displacement change along the first direction Y, i.e., which may enable the third driving member 133 and the rotation driving member 134 undergo a displacement change along the first direction Y, the first reflective mirror 2411 may also undergo a displacement change along the first direction Y accordingly due to a case that the first reflective mirror 2411 is disposed on the first micro-driving member 1313. In this way, a length of a measurement optical path between the first laser interferometer 2412 and the first reflective mirror 2411 may also change accordingly. That is, the first reflected laser beam generated by the first reflective mirror 2411 along the first direction Y may also change due to the displacement change of the first reflective mirror 2411, such that it may be possible to enable the first reflected laser beam received by the first laser interferometer 2412 to be changed correspondingly. Therefore, a state of formed interference fringes may be changed. In some embodiments, a change in spacings of the interference fringes and a change in the number of the interference fringes may be measured by the first system connection line and the computing system of the first laser interferometer unit 241, such that the displacement change of the third driving member 133 and the rotation driving member 134 along the first direction Y may be calculated, and thus it may be possible to obtain a displacement change of the bonding head 135 picking up the second component 40 along the first direction Y. In this way, the coordinate relationship of the first alignment mark B1, the second alignment mark B2, the third alignment mark T1, and the fourth alignment mark T2 along the first direction Y may be determined by the cooperation of the first laser interferometer 2412 and the first reflective mirror 2411. In other words, displacement information of the second component 40 along the first direction Y may be determined by the cooperation of the first laser interferometer 2412 and the first reflective mirror 2411.

In some embodiments, as shown in FIG. 7, the first-direction coordinate information related to the coordinate relationship of the first alignment mark B1, the second alignment mark B2, the third alignment mark T1, and the fourth alignment mark T2 along the first direction Y may be expressed in the following manner. That is, in the calibrated coordinate system, the first alignment mark B1, the second alignment mark B2, the third alignment mark T1, and the fourth alignment mark T2 may be assumed to be ordinate values on the Y-axis, respectively. For example, the first alignment mark B1, the second alignment mark B2, the third alignment mark T1, and the fourth alignment mark T2 may be respectively marked as B1 ( . . . , y_{B1}), B2 ( . . . , y_{B2}), T1 ( . . . , y_{T1}), and T2 ( . . . , y_{T2}), which may be the coordinate information along the first direction Y.

In some embodiments, in a structural design of the second laser interferometer unit 242, the second reflective mirror 2421 may be disposed on another side plate of the gantry 11, and the second laser interferometer 2422 may be disposed at a side plate of the base frame 12. Alternatively, the positions of the second reflective mirror 2421 and the second laser interferometer 2422 may be interchanged. That is, the second reflective mirror 2421 may be disposed at the side plate of the base frame 12. The second laser interferometer 2422 may be disposed on the another side plate of the gantry 11. In other words, the second reflective mirror 2421 may be disposed on one of another side plate of the gantry 11 and a side plate of the base frame 12, and the first laser interferometer 2422 may be disposed on the other one of the another side plate of the gantry 11 and the side plate of the base frame 12. In some embodiments, in a plane approximately parallel to the side plate of the base frame 12, a projection of the second reflective mirror 2421 may be at least partially overlapped with that of the second laser interferometer 2422. It may be understood that the plane approximately parallel to the side plate of the base frame 12 may be referred to a plane approximately parallel to the third direction Z shown in FIG. 2 and approximately perpendicular to the second direction X shown in FIG. 2, i.e., a plane approximately parallel to the third direction Z shown in FIG. 2 and approximately parallel to the first direction Y shown in FIG. 2. In some embodiments, the second laser interferometer 2422 may be configured to emit a second correction laser beam along the second direction X. The second reflective mirror 2421 may be configured to receive the second correction laser beam. The second reflective mirror 2421 may be configured to receive the second correction laser beam along the second direction X and generate a second reflected laser beam along the second direction X. The second laser interferometer 2422 may be configured to receive the second reflected laser beam. In this way, it may be possible to enable the second laser interferometer 2422 and the second reflective mirror 2421 to cooperate to determine the coordinate relationship of the first alignment mark B1, the second alignment mark B2, the third alignment mark T1, and the fourth alignment mark T2 along the second direction X. The second correction laser beam and the second reflected laser beam have a same fixed wavelength. In some embodiments, the second correction laser beam may be referred to as a second laser beam, and the second reflected laser beam may also be referred to as a reflected second laser beam.

In some embodiments, the second laser interferometer 2422 may include a second system connection line. The second system connection line may be configured to be connected to a computer system 243. Based on the determined coordinate relationship along the second direction X, the computer system 243 may be configured to generate second-direction coordinate information (i.e., the coordinate information along the second direction X) related to the coordinate relationship of the first alignment mark B1, the second alignment mark B2, the third alignment mark T1, and the fourth alignment mark T2 along the second direction X.

In some embodiments, when the second micro-driving member 1323 finely moves the gantry 11 in the horizontal plane along the second direction X to enable the gantry 11 to undergo a displacement change along the second direction X, the second reflective mirror 2421 may also undergo a displacement change along the second direction X accordingly due to a case that the second reflective mirror 2421 is disposed on the gantry 11. In this way, a length of a measurement optical path between the second laser interferometer 2422 and the second reflective mirror 2421 may also change accordingly. That is, the first reflected laser beam generated by the second reflective mirror 2421 along the second direction X may also change due to the displacement change of the second reflective mirror 2421, such that it may be possible to enable the first reflected laser beam received by the second laser interferometer 2422 second laser interferometer 2422 to be changed correspondingly. Therefore, a state of formed interference fringes may be changed. In some embodiments, a change in spacings of the interference fringes and a change in the number of the interference fringes may be measured by the second system connection line and the computing system of the second laser interferometer unit 242, such that the displacement change of the gantry 11 along the second direction X may be calculated, and thus it may be possible to obtain a displacement change of the bonding head 135 picking up the second component 40 along the second direction X. In this way, the coordinate relationship of the first alignment mark B1, the second alignment mark B2, the third alignment mark T1, and the fourth alignment mark T2 along the second direction X may be determined by the cooperation of the second laser interferometer 2422 and the second reflective mirror 2421. In other words, displacement information of the second component 40 along the second direction X may be determined by the cooperation of the second laser interferometer 2422 and the second reflective mirror 2421.

In some embodiments, as shown in FIG. 7, the second-direction coordinate information related to the coordinate relationship of the first alignment mark B1, the second alignment mark B2, the third alignment mark T1, and the fourth alignment mark T2 along the second direction X may be expressed in the following manner. That is, in the calibrated coordinate system, the first alignment mark B1, the second alignment mark B2, the third alignment mark T1, and the fourth alignment mark T2 may be assumed to be abscissa values on the X-axis, respectively. For example, the first alignment mark B1, the second alignment mark B2, the third alignment mark T1, and the fourth alignment mark T2 may be respectively marked as B1 (x_{B1}, . . . ), B2 (x_{B2}, . . . ), T1 (x_{T1}, . . . ), and T2 (x_{T2}, . . . ), which may be the coordinate information along the second direction X.

In this way, after the fixed coordinate in the calibrated coordinate system is determined, the first laser interferometer unit 241, the second laser interferometer unit 242, and the computer system 243 may cooperate to determine the coordinate information of the first alignment mark B1, the second alignment mark B2, the third alignment mark T1, and the fourth alignment mark T2 along the first direction Y and the coordinate information of the first alignment mark B1, the second alignment mark B2, the third alignment mark T1, and the fourth alignment mark T2 along the second direction X, which may be respectively marked as B1 (x_{B1}, y_{B1}), B2 (x_{B2}, y_{B2}), T1 (x_{T1}, y_{T1}), and T2 (x_{T2}, y_{T2}). Based on this, the first angle α1 may be determined through the coordinate information of B1 (x_{B1}, y_{B1}) and B2 (x_{B2}, y_{B2}), and the second angle α2 may be determined through the coordinate information of T1 (x_{T1}, y_{T1}), and T2 (x_{B2}, y_{T2}), thereby determining the angular deviation Δα between the first component 30 and the second component 40 in the calibrated coordinate system.

In some embodiments, based on the first-direction coordinate information and the second-direction coordinate information, such as B1 (x_{B1}, y_{B1}), B2 (x_{B2}, y_{B2}), T1 (x_{T1}, y_{T1}), and T2 (x_{T2}, y_{T2}), the computer system 243 may be configured to determine that the angular deviation Δα between the first component 30 and the second component 40 in the calibrated coordinate system is the difference between the first angle α1 and the second angle α2.

In some embodiments, the correction information may include the first-direction coordinate information, the second-direction coordinate information, and the angular deviation.

Therefore, in the structural design of the bonding apparatus provided by the embodiments of the present disclosure, based on the read first and second alignment marks or the read third and fourth alignment marks, the calibrated coordinate system may be defined by the computer system. In some embodiments, the reference mark may be disposed on the reference member or the other elements of the bonding apparatus, and when the reference assembly is disposed at a same position, the different coordinate information may be obtained by the first image acquisition member and the second image acquisition member, such that it may be possible to determine the fixed coordinate in the calibrated coordinate system.

In the bonding apparatus provided by the embodiments of the present disclosure, the computer system of the laser interferometer assembly is respectively connected to the first laser interferometer and the second laser interferometer. Based on the determined fixed coordinate, the computer system may be capable of generating the coordinate information of the first alignment mark, the second alignment mark, the third alignment mark, and the fourth alignment mark along the first direction and the coordinate information of the first alignment mark, the second alignment mark, the third alignment mark, and the fourth alignment mark along the second direction in the calibrated coordinate system. That is, by controlling the computer system, the displacement information along the first direction Y determined by the first laser interferometer and the first reflective mirror may be converted into the first-direction coordinate information in the calibrated coordinate system, such as B1 ( . . . , y_{B1}), B2 ( . . . , y_{B2}), T1 ( . . . , y_{T1}), and T2 ( . . . , y_{T2}). Similarly, by controlling the computer system, the displacement information along the second direction X determined by the second laser interferometer and the second reflective mirror may be converted into the second-direction coordinate information in the calibrated coordinate system, such as B1 (x_{B1}, . . . ), B2 (x_{B2}, . . . ), T1 (x_{T1}, . . . ), and T2 (x_{T2}, . . . ).

In some embodiments, based on the generated first-direction coordinate information and the generated second-direction coordinate information, the computer system 243 may further be capable of determining the angular deviation between the predetermined surface position of the first component and the position of the second component. The laser interferometer assembly may cooperate with the movable pick-up platform to adjust the position of the second component, such that it may be possible to determine a bonding alignment position of the first component and the second component, and thus the second component may be bonded to the predetermined surface position of the first component.

In some embodiments, when the angular deviation Δα is greater than a predetermined threshold, the laser interferometer assembly 24 may cooperate with the first macro-driving/micro-driving member, the second macro-driving/micro-driving member, the third driving member 133, and the rotation driving member 134 to implement the positioning with sub-micron accuracy along the first direction Y, the second direction X, and the third direction Z and implement positioning with micro-radian-level accuracy for the bonding head 135. In this way, the movable pick-up platform 13 may form a high-precision movement platform, such that the bonding head 135 may be driven to adjust the position of the second component 40 until the angular deviation Δα is less than or equal to the predetermined threshold. An angular deviation of the predetermined threshold may be 0°, 0.5°, or 1°. A specific value of the angular deviation of the predetermined threshold may be set according to specific design requirements, which is not limited herein. In some embodiments, the angular deviation of the predetermined threshold Δα=0°, i.e., α1′=α2. α1′ represents a third angle between a third connecting line L1′ and the X-axis direction in the calibrated coordinate system after the position of the second component 40 is adjusted, where the third connecting line L1′ is a connecting line between the third alignment mark T1 and the fourth alignment mark T2.

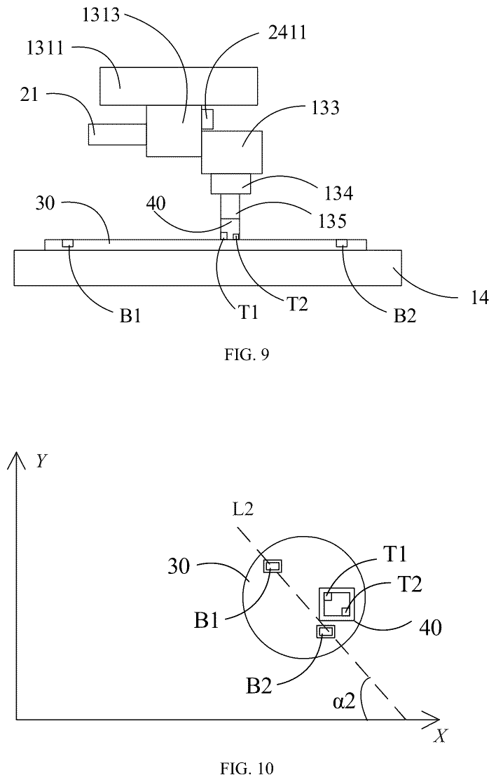

In some embodiments, as shown in FIGS. 8-10, FIG. 8 is a schematic diagram of a process in which the bonding apparatus corrects coordinate information of a relative position between the second component and the first component in the calibrated coordinate system according to some embodiments of the present disclosure. FIG. 9 is a schematic diagram of a process in which the bonding apparatus bonds the second component to a predetermined surface position of the first component according to some embodiments of the present disclosure. FIG. 10 is a schematic diagram of the coordinate information in the calibrated coordinate system when the second component is bonded to the predetermined surface position of the first component as shown in FIG. 9.

In some embodiments, as shown in FIG. 8, in the calibrated coordinate system, the coordinate information of the position of the second component 40 after being adjusted by the bonding head 135 may be described as follows. The coordinate information corresponding to the coordinate relationship of the third alignment mark T1 and the fourth alignment mark T2 along the first direction Y and the coordinate relationship of the third alignment mark T1 and the fourth alignment mark T2 along the second direction X may be described that in the calibrated coordinate system, a position of the third alignment mark T1 may be adjusted to (x′_{T1}, y_{T1}), and a position of the third alignment mark T2 may be adjusted to T2 (x′_{T2}, y′_{T2}). Thus, α1′ may be calculated through the adjusted coordinate information T1 (x′_{T1}, y′_{T1}) and T2 (x′_{T2}, y′_{T2}). In some embodiments, when α1′ is adjusted to meet the condition that the angular deviation Δα=0, i.e., α1′=α2, which indicates that the relative position between the first component 30 and the second component 40 reaches the predetermined threshold. At the same time, the coordinate information of the third alignment mark T1 and the fourth alignment mark T2 in the calibrated coordinate system may be illustrated in FIG. 10. In some embodiments, the third driving member of the movable pick-up platform may move the second component to the predetermined surface position of the first component, and the second component may be bonded to the predetermined surface position of the first component, as shown in FIG. 9.

In some embodiments, α1′ may be obtained in the following manner. The coordinate relationship of the third alignment mark T1 and the fourth alignment mark T2 along the first direction Y and the coordinate relationship of the third alignment mark T1 and the fourth alignment mark T2 along the second direction X may be obtained by two groups of reflective mirrors and laser interferometers. The computer system 243 may calculate the angular deviation Δα and the coordinate information of the third alignment mark T1 and the fourth alignment mark T2 along the first direction Y and the coordinate information of the third alignment mark T1 and the fourth alignment mark T2 along he second direction X, i.e., T1 (x′_{T1}, y′_{T1}) and T2 (x′_{T2}, y′_{T2}). Displacement differences between T1 (x′_{T1}, y′_{T1}) and T2 (x′_{T2}, y′_{T2}) and T1 (x_{T1}, y_{T1}) and T2 (x_{T2}, y_{T2}) may also be referred to as axial displacement differences, i.e., Δx and Δy. In some embodiments, α1′ may be compensated through a visual closed-loop, and the axial displacement differences Δx and Δy may be compensated through the two sets of laser interferometers in a closed-loop manner, respectively.

In the structural design of the bonding apparatus provided by the embodiments of the present disclosure, by arranging the laser interferometer assembly, the displacement change of the movable pick-up platform along the first direction may be measured by the first laser interferometer unit, such that the displacement information of the movable pick-up platform along the first direction may be determined. Further, the displacement change of the movable pick-up platform along the second direction may be measured by the second laser interferometer unit, such that the displacement information of the movable pick-up platform along the second direction may be determined. In addition, based on the displacement information of the movable pick-up platform along the first direction and he displacement information of the movable pick-up platform along the second direction, the coordinate information of the second component along the first direction and the coordinate information of the second component along the second direction may further be determined by the laser interferometer assembly. In this way, a high-precision motion closed-loop may be formed by the first laser interferometer unit, the second laser interferometer unit form, and the movable pick-up platform, such that it may be possible to implement precise positioning of the second component, and determine the bonding alignment position of the first and second components, thereby improving the bonding accuracy between the second component 40 and the first component 30.

In some embodiments, in the bonding apparatus provided in the embodiments of the present disclosure, the reference assembly may further be arranged, and configured to correct the relative position between the first component 30 and the second component 40 according to the correction information. In this way, by performing only a single recognition of the alignment mark (such as the first alignment mark B1, the second alignment mark B2) on the first component 30 and performing only a single recognition of the calibration mark on the reference element 23 in the reference assembly, it may be possible to determine both the calibrated coordinate system and the fixed coordinate in the calibrated coordinate system, such that the coordinate relationship of the alignment mark (such as the third alignment mark T1, the fourth alignment mark T2) on the second component 40 may further be determined in the calibrated coordinate system. Therefore, it may be possible to determine the correction information and correct the relative position between the first component 30 and the second component 40. Therefore, the bonding apparatus provided by the embodiments of the present disclosure may complete the alignment and bonding of the second component 40 and the first component 30 without requiring two cameras to simultaneously recognize the alignment mark on the first component 30 and the alignment mark on the second component 40 in a same field-of-view. At the same time, it is not necessary to perform multiple alignments for each second component 40, thereby effectively reducing the time consumption and improving the bonding efficiency and yield.

In some embodiments, since in the bonding apparatus provided by the embodiments of the present disclosure, since two image acquisition members and the reference member 23 may be used to simultaneously recognize the calibration mark on the reference member 23, a distribution of the alignment mark on the first component 30 and the alignment mark on the second component 40 is not limited. In this way, it may be possible to effectively reduce the influence of the field-of-view of the camera on the alignment mark on the first component 30 and the alignment mark on the second component 40.

In some embodiments, in the bonding apparatus provided by the embodiments of the present disclosure, the first macro-driving member/the first micro-driving member, the second macro-driving member/the second micro-driving member, the third driving member 133, and the rotation driving member 134 of the movable pick-up platform 13 may cooperate with the first laser interferometer unit 241 and the second laser interferometer unit 242 in the laser interferometer assembly 24, such that the motion closed-loop may be formed. In this way, it may be possible to enable the movable pick-up platform 13 to implement the positioning with sub-micron accuracy, thereby effectively improving the bonding accuracy.

It may be understood that the bonding apparatus provided in the embodiments of the present disclosure may be applied not only to a chip-to-wafer (C2W) bonding technology. That is, in the bonding apparatus described in the above embodiments, the high-precision movement platform and the motion closed-loop may be formed by the cooperation of the gantry 11, the base frame 12, the movable pick-up platform 13, and the laser interferometer assembly 24 in the machine base 10, such that a to-be-bonded chip may be moved to the predetermined surface position of the wafer and may be bonded to the predetermined surface position of a to-be-bonded wafer. In some embodiments, the bonding apparatus provided in the embodiments of the present disclosure may further be applied to a wafer-to-wafer (W2W) bonding technology. In the bonding apparatus described in the above embodiments, the high-precision movement platform and the motion closed-loop may be formed by the cooperation of the gantry 11, the base frame 12, the movable pick-up platform 13, and the laser interferometer assembly 24 in the machine base 10, such that a to-be-bonded first wafer may be moved to the predetermined surface position of the wafer and may be bonded to a predetermined surface position of a to-be-bonded second wafer. The working principle and the technical effect to be achieved, which is applied to the W2W bonding technology, may be basically the same as those applied to the C2W bonding technology, the specific content of which may refer to the relevant descriptions in the above embodiments. Similarly, the bonding apparatus provided in the embodiments of the present disclosure may further be applied to a chip-to-chip (C2C) bonding technology, and the working principle and the technical effect to be achieved, which is applied to the C2C bonding technology, may also be basically the same as those applied to the C2W bonding technology, the specific content of which may refer to the relevant descriptions in the above embodiments.

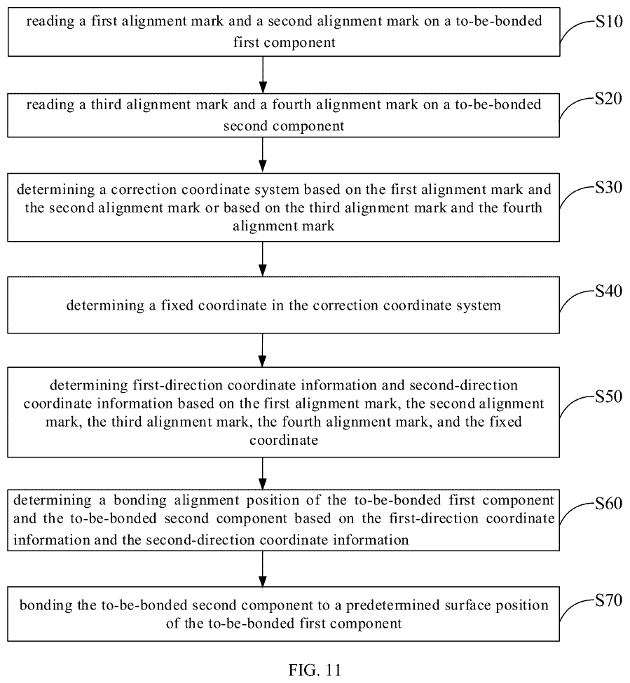

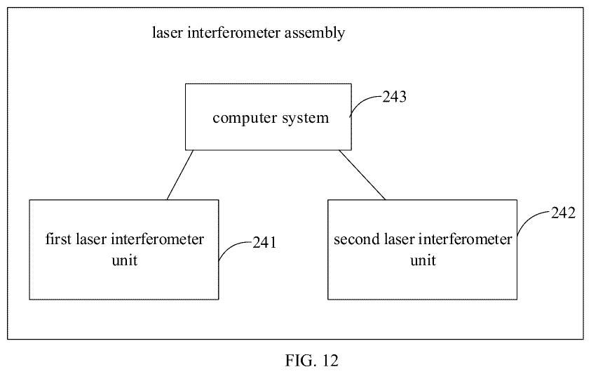

Based on the above-mentioned bonding apparatus, a method for bonding the second component 40 to the first component 30 by using the above-mentioned bonding apparatus may be described as follows. FIG. 11 is a schematic flowchart of a bonding method according to some embodiments of the present disclosure. The operation of the bonding method provided by the embodiments may be described in detail in combination with FIGS. 2-11.

In some embodiments, as shown in FIG. 11, the bonding method may be applied to the bonding apparatus 100 according to any one of the above-mentioned embodiments. The bonding method may include the following operations.

In an operation S10, a first alignment mark and a second alignment mark on a to-be-bonded first component may be read.

In some embodiments, as shown in FIG. 3, the first image acquisition member 21 may be driven to move with the first driving member 131 to the position above the first chuck 14 carrying the first component 30. That is, the field-of-view of the first image acquisition member 21 is positioned within an area where the first component 30 is located. At this time, the first image acquisition member 21 may read the first alignment mark B1 and the second alignment mark B2 on the first component 30. In some embodiments, based on the read first alignment mark B1 and the second alignment mark B2, the second image acquisition member 22 may cooperate with the reference member 23 and the first image acquisition member 21 to define the calibrated coordinate system, as shown in FIG. 5.

In an operation S20, a third alignment mark and a fourth alignment mark on a to-be-bonded second component may be read.

In some embodiments, as shown in FIG. 6, the movable pick-up platform 13 may be controlled to pick up the second component 40 through the bonding head 135, and the picked-up second component 40 may be moved to the position above the second image acquisition member 22 until the field-of-view of the second image acquisition member 22 is positioned below the third alignment mark T1 and the fourth alignment mark T2 on the second component 40, i.e., a position may correspond to a direction of an end of the bonding head 135 facing the second image acquisition member 22. Therefore, the second image acquisition member 22 may read the third alignment mark T1 and the fourth alignment mark T2 on the second component 40. In this way, the third alignment mark T1 and the fourth alignment mark T2 on the second component 40 picked up by the bonding head 135 may be read by the second image acquisition member 22.

In an operation S30, a calibrated coordinate system may be determined based on the first alignment mark and the second alignment mark or based on the third alignment mark and the fourth alignment mark.

In an operation S40, a fixed coordinate in the calibrated coordinate system may be determined.

In some embodiments, as shown in FIG. 4, the operation S40 may include the following implementation process. The first image acquisition member 21 may be driven to move with the first driving member 131. For example, the first image acquisition member 21 may be driven to move to the position above the second image acquisition member 22 until a connecting line between a center point of the first image acquisition member 21 and a center point of the second image acquisition member 22 is approximately perpendicular to a plane at which the first chuck 14 is located, i.e., the center point of the first image acquisition member 21 and the center point of the second image acquisition member 22 may be aligned with each other in a direction approximately parallel to the third direction Z. In some embodiments, the reference member 23 is moved to the position above the second image acquisition member 22, and is moved to be located between the first image acquisition member 21 and the second image acquisition member 22. At this time, a connecting line between the center point of the first image acquisition member 21, a center point of the reference member 23, and the center point of the second image acquisition member 22 may be approximately perpendicular to the plane at which the first chuck 14 is located. In this way, the reference mark 231 may be simultaneously recognized by the first image acquisition member 21 and the second image acquisition member 22, such that it may be possible to determine the fixed coordinate in the calibrated coordinate system.

In this way, the calibrated coordinate system and the fixed coordinate shown in FIG. 5 may be obtained through the operations S10 to S40.

In an operation S50, first-direction coordinate information and second-direction coordinate information may be determined based on the first alignment mark, the second alignment mark, the third alignment mark, the fourth alignment mark alignment mark, and the fixed coordinate.

In some embodiments, the operation S50 may include: controlling the first laser interferometer unit 241 to generate the first-direction coordinate information related to the coordinate relationship of the first alignment mark B1, the second alignment mark B2, the third alignment mark T1, and the fourth alignment mark T2 along the first direction Y in the calibrated coordinate system; and controlling the second laser interferometer unit 242 to generate the second-direction coordinate information related to the coordinate relationship of the first alignment mark B1, the second alignment mark B2, the third alignment mark T1, and the fourth alignment mark T2 along the second direction X in the calibrated coordinate system.

In some embodiments, the operation of generating the first-direction coordinate information may include: determining, by the first laser interferometer and the first reflective mirror, displacement information of the movable pick-up platform along the first direction; and generating coordinate information of the first alignment mark, the second alignment mark, the third alignment mark, and the fourth alignment mark along the first direction in the calibrated coordinate system, based on the displacement information along the first direction. In some embodiments, the first laser interferometer 2412 may be controlled to emit a first correction laser beam along the first direction Y. The first reflective mirror 2411 may receive the first correction laser beam and generate a first reflected laser beam along the first direction Y. The first laser interferometer 2412 may be controlled to receive the first reflected laser beam. In some embodiments, when the first micro-driving member 1313 finely moves the third driving member 133 and the rotation driving member 134 in the horizontal plane along the first direction Y, resulting in a displacement change along the first direction Y, i.e., which may enable the third driving member 133 and the rotation driving member 134 undergo a displacement change along the first direction Y, the first reflective mirror 2411 may also undergo a displacement change along the first direction Y accordingly due to a case that the first reflective mirror 2411 is disposed on the first micro-driving member 1313. In this way, a length of a measurement optical path between the first laser interferometer 2412 and the first reflective mirror 2411 may also change accordingly. That is, the first reflected laser beam generated by the first reflective mirror 2411 along the first direction Y may also change due to the displacement change of the first reflective mirror 2411, such that it may be possible to enable the first reflected laser beam received by the first laser interferometer 2412 to be changed correspondingly. Therefore, a state of formed interference fringes may be changed. In some embodiments, a change in spacings of the interference fringes and a change in the number of the interference fringes may be measured by the first system connection line and the computing system of the first laser interferometer unit 241, such that the displacement change of the third driving member 133 and the rotation driving member 134 along the first direction Y may be calculated, and thus it may be possible to obtain a displacement change of the second component 40 along the first direction Y. In this way, the coordinate relationship of the first alignment mark B1, the second alignment mark B2, the third alignment mark T1, and the fourth alignment mark T2 along the first direction Y may be determined by the cooperation of the first laser interferometer 2412 and the first reflective mirror 2411. In other words, displacement information of the second component 40 along the first direction Y may be determined by the cooperation of the first laser interferometer 2412 and the first reflective mirror 2411. In some embodiments, based on the determined displacement information of the first alignment mark B1, the second alignment mark B2, the third alignment mark T1, and the fourth alignment mark T2 along the first direction Y, the computer system 243 connected to the first laser interferometer 2412 may generate first-direction coordinate information related to the coordinate relationship of the first alignment mark B1, the second alignment mark B2, the third alignment mark T1, and the fourth alignment mark T2 along the first direction Y.

In some embodiments, as shown in FIG. 7, the first-direction coordinate information related to the coordinate relationship of the first alignment mark B1, the second alignment mark B2, the third alignment mark T1, and the fourth alignment mark T2 along the first direction Y may be expressed in the following manner. That is, in the calibrated coordinate system, the first alignment mark B1, the second alignment mark B2, the third alignment mark T1, and the fourth alignment mark T2 may be assumed to be ordinate values on the Y-axis, respectively. For example, the first alignment mark B1, the second alignment mark B2, the third alignment mark T1, and the fourth alignment mark T2 may be respectively marked as B1 ( . . . , y_{B1}), B2 ( . . . , y_{B2}), T1 ( . . . , y_{T1}), and T2 ( . . . , y_{T2}), which may be the coordinate information along the first direction Y.

Similarly, the operation of generating the second-direction coordinate information may include: determining, by the second laser interferometer and the second reflective mirror, displacement information of the movable pick-up platform along the second direction; and generating coordinate information of the first alignment mark, the second alignment mark, the third alignment mark, and the fourth alignment mark along the second direction in the calibrated coordinate system, based on the displacement information along the second direction. In some embodiments, the second laser interferometer 2422 may be controlled to emit a second correction laser beam along the second direction X. The second reflective mirror 2421 may receive the second correction laser beam and generate a second reflected laser beam along the second direction X. The second laser interferometer 2422 may be controlled to receive the second reflected laser beam. In some embodiments, when the second micro-driving member 1323 finely moves the gantry 11 in the horizontal plane along the second direction X to enable the gantry 11 to undergo a displacement change along the second direction X, the second reflective mirror 2421 may also undergo a displacement change along the second direction X accordingly due to a case that the second reflective mirror 2421 is disposed on the gantry 11. In this way, a length of a measurement optical path between the second laser interferometer 2422 and the second reflective mirror 2421 may also change accordingly. That is, the first reflected laser beam generated by the second reflective mirror 2421 along the second direction X may also change due to the displacement change of the second reflective mirror 2421, such that it may be possible to enable the first reflected laser beam received by the second laser interferometer 2422 second laser interferometer 2422 to be changed correspondingly. Therefore, a state of formed interference fringes may be changed. In some embodiments, a change in spacings of the interference fringes and a change in the number of the interference fringes may be measured by the second system connection line and the computing system of the second laser interferometer unit 242, such that the displacement change of the gantry 11 along the second direction X may be calculated, and thus it may be possible to obtain a displacement change of the bonding head 135 picking up the second component 40 along the second direction X. In this way, the coordinate relationship of the first alignment mark B1, the second alignment mark B2, the third alignment mark T1, and the fourth alignment mark T2 along the second direction X may be determined by the cooperation of the second laser interferometer 2422 and the second reflective mirror 2421. In other words, displacement information of the second component 40 along the second direction X may be determined by the cooperation of the second laser interferometer 2422 and the second reflective mirror 2421. In some embodiments, based on the determined displacement information of the first alignment mark B1, the second alignment mark B2, the third alignment mark T1, and the fourth alignment mark T2 along the second direction X, the computer system 243 connected to the first laser interferometer 2412 may generate second-direction coordinate information related to the coordinate relationship of the first alignment mark B1, the second alignment mark B2, the third alignment mark T1, and the fourth alignment mark T2 along the second direction X.

In some embodiments, as shown in FIG. 7, the second-direction coordinate information related to the coordinate relationship of the first alignment mark B1, the second alignment mark B2, the third alignment mark T1, and the fourth alignment mark T2 along the second direction X may be expressed in the following manner. That is, in the calibrated coordinate system, the first alignment mark B1, the second alignment mark B2, the third alignment mark T1, and the fourth alignment mark T2 may be assumed to be abscissa values on the X-axis, respectively. For example, the first alignment mark B1, the second alignment mark B2, the third alignment mark T1, and the fourth alignment mark T2 may be respectively marked as B1 (x_{B1}, . . . ), B2 (x_{B2}, . . . ), T1 (x_{T1}, . . . ), and T2 (x_{T2}, . . . ), which may be the coordinate information along the second direction X.

In this way, the coordinate information in the calibrated coordinate system shown in FIG. 7 may be obtained through the operation S50. In some embodiments, the coordinate information may be marked as B1 (x_{B1}, y_{B1}), B2 (x_{B2}, y_{B2}), T1 (x_{T1}, y_{T1}), and T2 (x_{T2}, y_{T2}) in the calibrated coordinate system.

It may be understood that there is no sequence of precedence among the above-mentioned operations S20 to S50 of the bonding method in the embodiments of the present disclosure, as long as the coordinate information in the calibrated coordinate system shown in FIG. 7, such as B1 (x_{B1}, y_{B1}), B2 (x_{B2}, y_{B2}), T1 (x_{T1}, y_{T1}), and T2 (x_{T2}, y_{T2}) in the calibrated coordinate system, may be obtained through the above-mentioned operations. For example, after determining the fixed coordinate in the calibrated coordinate system through the operation S40, the reference member 23 may be moved away (for example, the reference member 23 may be moved out of the maximum field-of-view of the first/second image acquisition members), and the operation S20 may be performed.

In an operation S60, a bonding alignment position of the first component and the second component may be determined based on the first-direction coordinate information and the second-direction coordinate information.

In some embodiments, the operation S60 may include: determining an angular deviation based on coordinate information of the first alignment mark, the second alignment mark, the third alignment mark, and the fourth alignment mark along a first direction and coordinate information of the first alignment mark, the second alignment mark, the third alignment mark, and the fourth alignment mark along a second direction; determining correction information based on the first-direction coordinate information, the second-direction coordinate information, and the angular deviation; correcting a relative position between the first component and the second component based on the correction information; and determining the bonding alignment position of the first component and the second component based on the corrected relative position.

In some embodiments, based on the coordinate information, such as B1 (x_{B1}, y_{B1}), B2 (x_{B2}, y_{B2}), T1 (x_{T1}, y_{T1}), and T2 (x_{T2}, y_{T2}), determined in the operation S50, the first angle α1 may be determined through the coordinate information of B1 (x_{B1}, y_{B1}) and B2 (x_{B2}, y_{B2}), and the second angle α2 may be determined through the coordinate information of T1 (x_{T1}, y_{T1}) and T2 (x_{T2}, y_{T2}), so as to determine the angular deviation Δα between the first component 30 and the second component 40 in the calibrated coordinate system, as shown in FIG. 7. In the calibrated coordinate system, the first connecting line between the third alignment mark T1 and the fourth alignment mark T2 on the second component 40 may be assumed to be L1, i.e., a connecting line between B1 and B2. The first angle between the L1 and the X-axis direction in the calibrated coordinate system may be assumed to be α1. The second connecting line between the first alignment mark B1 and the second alignment mark B2 on the first component 30 may be assumed to be L2, i.e., a connecting line between T1 and T2. The second angle between the L2 and the X-axis direction in the calibrated coordinate system may be assumed to be α2. The angular deviation Δα between the first component 30 and the second component 40 in the calibrated coordinate system is the absolute value of the difference between the first angle α1 and the second angle α2.

In some embodiments, the operation of determining the bonding alignment position of the first component and the second component based on the corrected relative position may include: rotating the bonding head 135 to correct the angular deviation to be within a predetermined threshold based on the angular deviation; reading first-direction verification coordinate information and second-direction verification coordinate information of the second component 40; and verifying a correction result of the angular deviation based on the read first-direction verification coordinate information and the read second-direction verification coordinate information of the second component 40. In some embodiments, when the angular deviation Δα is greater than a predetermined threshold, the laser interferometer assembly 24 cooperates with the first macro-driving/micro-driving member, the second macro-driving/micro-driving member, the third driving member 133, and the rotation driving member 134 to implement the positioning with sub-micron accuracy along the first direction Y, the second direction X, and the third direction Z and implement positioning with micro-radian-level accuracy for the bonding head 135. In this way, the movable pick-up platform 13 may form a high-precision movement platform, such that the bonding head 135 may be driven to adjust the position of the second component 40 until the angular deviation Δα is less than or equal to the predetermined threshold. An angular deviation of the predetermined threshold may be 0°, 0.5°, or 1°. A specific value of the angular deviation of the predetermined threshold may be set according to specific design requirements, which is not limited herein. In some embodiments, the angular deviation of the predetermined threshold Δα=0°, i.e., α1′=α2. α1′ represents a third angle between a third connecting line L1′ and the X-axis direction in the calibrated coordinate system after the position of the second component 40 is adjusted, where the third connecting line L1′ is a connecting line between the third alignment mark T1 and the fourth alignment mark T2.

In some embodiments, as shown in FIG. 8, in the calibrated coordinate system, the coordinate information of the position of the second component 40 after being adjusted by the bonding head 135 may be described as follows. The coordinate information corresponding to the coordinate relationship of the third alignment mark T1 and the fourth alignment mark T2 along the first direction Y and the coordinate relationship of the third alignment mark T1 and the fourth alignment mark T2 along the second direction X may be described that in the calibrated coordinate system, a position of the third alignment mark T1 may be adjusted to (x′_{T1}, y_{T1}), and a position of the third alignment mark T2 may be adjusted to T2 (x′_{T2}, y_{T2}). Thus, α1′ may be calculated through the adjusted coordinate information T1 (x′_{T1}, y_{T1}) and T2 (x′_{T2}, y′_{T2}).

In an operation S70, the second component may be bonded to a predetermined surface position of the first component.

In some embodiments, when α1′ is adjusted to meet the condition that the angular deviation Δα=0, i.e., α1′=α2, which indicates that the relative position between the first component 30 and the second component 40 reaches the predetermined threshold. At the same time, the coordinate information of the third alignment mark T1 and the fourth alignment mark T2 in the calibrated coordinate system may be illustrated in FIG. 10. In some embodiments, the third driving member of the movable pick-up platform may move the second component to the predetermined surface position of the first component, and the second component may be bonded to the predetermined surface position of the first component, as shown in FIG. 9.

The bonding method provided in the embodiments of the present disclosure may be applied to the above-mentioned bonding apparatus, and therefore the bonding method may also have the same technical effect, which will not be repeated herein.

The above is only some embodiments of the present disclosure, and is not intended to limit the scope of the present disclosure. Any equivalent structure or equivalent process transformation using the contents and the accompanying drawings of the present disclosure, or any direct or indirect application in other related technical fields, is included in the scope of the present disclosure.

1. A bonding apparatus, comprising:
a machine base, comprising a movable pick-up platform; and
a laser interferometer assembly comprising:
a first laser interferometer unit, configured to determine displacement information of the movable pick-up platform along a first direction; and
a second laser interferometer unit, configured to determine displacement information of the movable pick-up platform along a second direction;
wherein based on the displacement information along the first direction and the displacement information along the second direction, the laser interferometer assembly is further configured to determine coordinate information of the movable pick-up platform.

2. The bonding apparatus according to claim 1, wherein the first laser interferometer unit comprises a first reflective mirror and a first laser interferometer, and the first reflective mirror and the first laser interferometer are configured to synchronously move with the movable pick-up platform along the second direction; and
the second laser interferometer unit comprises a second reflective mirror and a second laser interferometer, and the second reflective mirror and the second laser interferometer are configured to move with the movable pick-up platform along the first direction.

3. The bonding apparatus according to claim 2, wherein the machine base further comprises a base frame and a gantry disposed on the base frame;
wherein a position of the first laser interferometer unit is controlled by the gantry;
the first reflective mirror is disposed on one of the movable pick-up platform and a side plate of the gantry, and the first laser interferometer is disposed on the other one of the movable pick-up platform and the side plate of the gantry;
in a plane approximately parallel to the side plate of the gantry, a projection of the first reflective mirror is at least partially overlapped with that of the first laser interferometer; and
based on a displacement change of the movable pick-up platform along the first direction, the first reflective mirror and the first laser interferometer cooperate to determine the displacement information of the movable pick-up platform along the first direction.

4. The bonding apparatus according to claim 3, wherein in the plane approximately parallel to the side plate of the gantry, the projection of the first reflective mirror is at least partially overlapped with that of the first laser interferometer;
the first laser interferometer is configured to emit a first correction laser beam along the first direction, and the first reflective mirror is configured to receive the first correction laser beam;
the first reflective mirror is configured to receive the first correction laser beam along the first direction and generate a first reflected laser beam along the first direction; and
the first laser interferometer is configured to receive the first reflected laser beam.

5. The bonding apparatus according to claim 3, wherein a position of the second laser interferometer unit is controlled by the gantry and the base frame;
the second reflective mirror is disposed on one of another side plate of the gantry and a side plate of the base frame, and the second laser interferometer is disposed on the other one of the another side plate of the gantry and the side plate of the base frame;
in a plane approximately parallel to the side plate of the base frame, a projection of the second reflective mirror is at least partially overlapped with that of the second laser interferometer; and
based on a displacement change of the movable pick-up platform along the second direction, the second reflective mirror and the second laser interferometer cooperate to determine the displacement information of the movable pick-up platform along the second direction.

6. The bonding apparatus according to claim 5, wherein in a plane approximately parallel to the side plate of the base frame, a projection of the second reflective mirror is at least partially overlapped with that of the second laser interferometer;
the second laser interferometer is configured to emit a second correction laser beam along the second direction, and the second reflective mirror is configured to receive the second correction laser beam;
the second reflective mirror is configured to receive the second correction laser beam along the second direction and generate a second reflected laser beam along the second direction; and
the second laser interferometer is configured to receive the second reflected laser beam.

7. The bonding apparatus according to claim 5, further comprising:
a first chuck, configured to carry a to-be-bonded first component;
a first image acquisition member, disposed at a side of the movable pick-up platform and having a first viewing angle, and configured to read a first alignment mark and a second alignment mark on the first component; and
a second image acquisition member, disposed on the machine base and having a second viewing angle, and configured to read a third alignment mark and a fourth alignment mark on a second component picked up by the movable pick-up platform.

8. The bonding apparatus according to claim 7, wherein in a case where a field-of-view of the first image acquisition member is within an area where the to-be-bonded first component is located, the first image acquisition member is configured to read the first alignment mark and the second alignment mark on the to-be-bonded first component; and
in a case where to-be-bonded the second component picked up by the movable pick-up platform is moved into a field-of-view of the second image acquisition member, the second image acquisition member is configured to read the third alignment mark and the fourth alignment mark on the to-be-bonded second component.

9. The bonding apparatus according to claim 7, further comprising a reference assembly disposed on the machine base;
wherein the reference assembly is arranged with a reference mark, and in a case where the reference assembly is disposed at a same position, the first image acquisition member and the second image acquisition member are configured to obtain different coordinate information by recognizing the reference mark, and a fixed coordinate in a calibrated coordinate system is determined.

10. The bonding apparatus according to claim 9, wherein the reference assembly is capable of being driven to move freely between a top plate of the gantry and the second image acquisition member, and a free movement range of the reference assembly is not less than an intersection of a maximum field-of-view of the first image acquisition member and a maximum field-of-view of the second image acquisition member.

11. The bonding apparatus according to claim 9, wherein the reference assembly comprises the reference member, and the reference member comprises one of a transparent component, a translucent component, and a structural component with a through-hole.

12. The bonding apparatus according to claim 7, wherein the laser interferometer assembly further comprises a computer system connected to the first laser interferometer and the second laser interferometer, respectively;
wherein based on the read first alignment mark and the read second alignment mark or based on the read third alignment mark and the read fourth alignment mark, the computer system is configured to define the calibrated coordinate system;
based on the determined fixed coordinate, the computer system is configured to generate coordinate information along the first direction and coordinate information along the second direction in the calibrated coordinate system for the first alignment mark, the second alignment mark, the third alignment mark, and the fourth alignment mark; and
based on the generated coordinate information along the first direction and the generated coordinate information along the second direction, the computer system is further configured to determine an angular deviation between a predetermined surface position of the first component and a position of the second component, the laser interferometer assembly is configured to cooperate with the movable pick-up platform to adjust the position of the second component, and the second component is bonded to the predetermined surface position of the first component.

13. The bonding apparatus according to claim 9, wherein the second image acquisition member is arranged with a reference mark, and the first image acquisition member is configured to determine the fixed coordinate in the calibrated coordinate system by reading the reference mark.

14. The bonding apparatus according to claim 7, wherein the movable pick-up platform comprises:
a bonding head, configured to pick up the to-be-bonded second component;
a first driving member; and
a second driving member;
wherein the first driving member comprises:
a first macro-driving member, disposed at a side of a top plate of the gantry facing the first chuck and configured to move the bonding head along the first direction in a horizontal plane; and
a first micro-driving member, disposed at a side of the first macro-driving member opposite to the top plate and configured to finely move the bonding head along the first direction in the horizontal plane; and
wherein the second driving member comprises:
a second macro-driving member, disposed at a side of a bottom plate of the base frame facing the gantry and configured to move the bonding head along the second direction in the horizontal plane; and
a second micro-driving member, connected to the second macro-driving member and the gantry and configured to finely move the bonding head along the second direction in the horizontal plane.

15. A bonding method, comprising:
reading a first alignment mark and a second alignment mark on a to-be-bonded first component;
reading a third alignment mark and a fourth alignment mark on a to-be-bonded second component;
determining a calibrated coordinate system based on the first alignment mark and the second alignment mark or based on the third alignment mark and the fourth alignment mark;
determining a fixed coordinate in the calibrated coordinate system;
determining first-direction coordinate information and second-direction coordinate information based on the first alignment mark, the second alignment mark, the third alignment mark, the fourth alignment mark, and the fixed coordinate;
determining a bonding alignment position of the to-be-bonded first component and the to-be-bonded second component based on the first-direction coordinate information and the second-direction coordinate information; and
bonding the to-be-bonded second component to a predetermined surface position of the to-be-bonded first component.

16. The bonding method according to claim 15, wherein the determining a bonding alignment position of the to-be-bonded first component and the to-be-bonded second component based on the first-direction coordinate information and the second-direction coordinate information, comprises:
determining an angular deviation based on coordinate information of the first alignment mark, the second alignment mark, the third alignment mark, and the fourth alignment mark along a first direction and coordinate information of the first alignment mark, the second alignment mark, the third alignment mark, and the fourth alignment mark along a second direction;
correcting a relative position between the to-be-bonded first component and the to-be-bonded second component based on the angular deviation; and
determining the bonding alignment position of the to-be-bonded first component and the to-be-bonded second component based on the corrected relative position.

17. The bonding method according to claim 16, wherein the correcting a relative position between the to-be-bonded first component and the to-be-bonded second component based on the angular deviation, comprises:
rotating a bonding head to correct the angular deviation to be within a predetermined threshold based on the angular deviation;
reading first-direction verification coordinate information and second-direction verification coordinate information of the to-be-bonded second component; and
verifying a correction result of the angular deviation based on the read first-direction verification coordinate information and the read second-direction verification coordinate information of the to-be-bonded second component.

18. The bonding method according to claim 15, wherein the determining a fixed coordinate in the calibrated coordinate system, comprises:
obtaining, by a first image acquisition member and a second image acquisition member, different coordinate information by recognizing a reference mark, and determining the fixed coordinate by reading the different coordinate information, in a case where a reference assembly is disposed at a same position.

19. The bonding method according to claim 15, wherein the determining first-direction coordinate information and second-direction coordinate information based on the first alignment mark, the second alignment mark, the third alignment mark, the fourth alignment mark, and the fixed coordinate, comprises:
controlling a first laser interferometer unit to generate displacement information of the first alignment mark, the second alignment mark, the third alignment mark, and the fourth alignment mark along the first direction in the calibrated coordinate system, and controlling a computer system to convert the displacement information along the first direction into coordinate information along the first direction; and
controlling a second laser interferometer unit to generate displacement information of the first alignment mark, the second alignment mark, the third alignment mark, and the fourth alignment mark along the second direction in the calibrated coordinate system, and controlling the computer system to convert the displacement information along the second direction into coordinate information along the second direction.

20. The bonding method according to claim 19, wherein
the controlling a first laser interferometer unit to generate displacement information of the first alignment mark, the second alignment mark, the third alignment mark, and the fourth alignment mark along the first direction in the calibrated coordinate system, comprises:
determining, by the first laser interferometer and the first reflective mirror, displacement information of the movable pick-up platform along the first direction; and
generating coordinate information of the first alignment mark, the second alignment mark, the third alignment mark, and the fourth alignment mark along the first direction in the calibrated coordinate system, based on the displacement information along the first direction; and
wherein the controlling a second laser interferometer unit to generate displacement information of the first alignment mark, the second alignment mark, the third alignment mark, and the fourth alignment mark along the second direction in the calibrated coordinate system, comprises:
determining, by the second laser interferometer and the second reflective mirror, displacement information of the movable pick-up platform along the second direction; and
generating coordinate information of the first alignment mark, the second alignment mark, the third alignment mark, and the fourth alignment mark along the second direction in the calibrated coordinate system, based on the displacement information along the second direction.
